(19) United States
(12) Patent Application Publication
(10) Pub. No.: US 2026/0143792 A1
(43) Pub. Date: May 21, 2026

(54) SEMICONDUCTOR DEVICE AND METHOD FOR FORMING THE SAME

(71) Applicant: United Microelectronics Corp., Hsinchu (TW)

(72) Inventors: Wen-Che Kuo, Taichung City (TW); Tsung-Yu Yang, Chiayi County (TW); Chang-Ta Chiang, Hsinchu City (TW)

(73) Assignee: United Microelectronics Corp., Hsinchu (TW)

(21) Appl. No.: 18/985,045

(22) Filed: Dec. 18, 2024

(30) Foreign Application Priority Data
Nov. 20, 2024 (TW) 113144588

(51) Int. Cl. H10D 84/80; H10D 1/47; H10D 84/01

(52) U.S. Cl. CPC H10D 84/817; H10D 1/47; H10D 84/0135; H10D 84/0151

(57) ABSTRACT

The present disclosure provides a semiconductor device and a method for forming the same. The semiconductor device includes a substrate including an active region defining by an isolation trench, an isolation structure disposed in the isolation trench and including a recess, and a thin film resistor structure disposed over the recess.

### CROSS-REFERENCE TO RELATED APPLICATION

This application claims the priority benefit of Taiwan application serial no. 113144588, filed on Nov. 20, 2024. The entirety of the above-mentioned patent application is hereby incorporated by reference herein and made a part of this specification.

### BACKGROUND

### Technical Field

The present invention relates to a semiconductor device and a method of forming the same.

### Description of Related Art

Generally, a polysilicon may be used as a gate material for a metal-oxide-semiconductor field-effect transistor (MOSFET) (also known as a polysilicon gate). However, to further improve the performance of the MOSFET, the process of replacing the polysilicon gate with a metal gate is gradually applied in the process of forming the MOSFET. However, passive elements such as resistors integrated in the MOSFET process are also affected by the process of forming the metal gate. For example, the supporting structure used to support the resistor and formed by the polysilicon material is also affected by the process of replacing the polysilicon gate with the metal gate, so that the supporting structure is formed by the same material as the metal gate. However, the metal (e.g., Cu) in the supporting structure may have an extrusion phenomenon caused by the thermal cycling processes during the front-end-of-line (FEOL) process and/or the back-end-of-line (BEOL) process, and thereby resulting to a burn out phenomenon between the resistor formed on the supporting structure and a conductive layer in the interconnection layer.

As electronic devices are designed towards miniaturization and in the case where performance requirements for the electronic devices by users are gradually increasing, the impact of the above-mentioned phenomenon becomes more severe, causing the current electronic devices to be insufficient to meet current or future-expected requirements.

### SUMMARY

The present invention provides a semiconductor device and a method for forming the same, in which an isolation structure is designed to include a recess and the thin film resistor structure is designed to dispose over the recess, so that a supporting structure under the thin film resistor structure is not affected by a process of replacing polysilicon gates with metal gates. As such, the supporting structure will not have the extrusion phenomenon caused by the thermal cycling processes during the front-end-of-line (FEOL) process and/or the back-end-of-line (BEOL) process, and thereby avoiding the burn out phenomenon between the thin film resistor structure above the supporting structure and the conductive layer in the interconnection layer.

An embodiment of the present invention provides a semiconductor device including a substrate, an isolation structure, and a thin film resistor structure. The substrate includes an active region defined by an isolation trench. The isolation structure is disposed in the isolation trench and includes a recess. The thin film resistor structure is disposed over the recess.

In some embodiments, a top surface of the active region is higher than a bottom surface of the recess.

In some embodiments, the semiconductor device further includes a supporting structure disposed on the recess and located under the thin film resistor structure.

In some embodiments, the semiconductor device further includes a gate structure disposed on the active region, wherein the gate structure includes a metal material different from a material of the supporting structure.

In some embodiments, the supporting structure includes polysilicon and is electrically floating.

In some embodiments, a top surface of the gate structure is higher than a top surface of the supporting structure.

In some embodiments, the thin film resistor structure includes a material having a resistance higher than the metal material of the gate structure.

In some embodiments, the semiconductor device further includes a first dielectric layer disposed on the substrate and surrounding the gate structure and the supporting structure. The first dielectric layer exposes a top surface of the gate structure and includes a portion interposed between the thin film resistor structure and the supporting structure and covering a top surface of the supporting structure.

In some embodiments, the semiconductor device further includes a second dielectric layer disposed on the first dielectric layer. The second dielectric layer includes a portion in contact with the top surface of the gate structure and a portion interposed between the thin film resistor structure and the supporting structure.

In some embodiments, a bottom surface of the thin film resistor structure in contact with the second dielectric layer is higher than the top surface of the gate structure in contact with the second dielectric layer.

An embodiment of the present invention provides a method of forming a semiconductor device, which includes the following steps. A substrate including an active region defined by an isolation trench is provided. An isolation structure is formed in the isolation trench. A recess is formed in the isolation structure. A thin film resistor structure is formed over the recess.

In some embodiments, a top surface of the active region is formed to be higher than a bottom surface of the recess.

In some embodiments, the method of forming the semiconductor device further includes forming a supporting structure on the recess, wherein the supporting structure is formed under the thin film resistor structure.

In some embodiments, the method of forming the semiconductor device further includes forming a gate structure on the active region, wherein the gate structure includes a metal material different from a material of the supporting structure.

In some embodiments, the supporting structure includes polysilicon and is electrically floating.

In some embodiments, the thin film resistor structure includes a material having a higher resistance than the metal material of the gate structure.

In some embodiments, the method of forming the semiconductor device further includes forming a first dielectric layer on the substrate surrounding the gate structure and the supporting structure. The first dielectric layer exposes a top surface of the gate structure and includes a portion interposed between the thin film resistor structure and the supporting structure and covering a top surface of the supporting structure.

In some embodiments, a step of forming the supporting structure and the gate structure includes: forming the supporting structure and a sacrificial gate structure on the recess and the active region, respectively, wherein the supporting structure and the sacrificial gate structure are made of the same material; forming a first dielectric material layer on the substrate covering the sacrificial gate structure and the supporting structure; removing a portion of the first dielectric material layer to form a first dielectric layer exposing a top surface of the sacrificial gate structure; removing the sacrificial gate structure to define a space in the first dielectric layer for forming the gate structure; and forming the gate structure in the space.

In some embodiments, the method of forming the semiconductor device further includes forming a second dielectric layer on the first dielectric layer. The second dielectric layer includes a portion in contact with the top surface of the gate structure and a portion interposed between the thin film resistor structure and the supporting structure.

In some embodiments, a bottom surface of the thin film resistor structure in contact with the second dielectric layer is higher than the top surface of the gate structure in contact with the second dielectric layer.

Based on the above, in the semiconductor device and the method for forming the same, the isolation structure is designed to include the recess and the thin film resistor structure is designed to dispose over the recess, so that the supporting structure under the thin film resistor structure is not affected by the process of replacing the polysilicon gates with the metal gates. As such, the supporting structure will not have the extrusion phenomenon caused by the thermal cycling processes during the FEOL process and/or the BEOL process, and thereby avoiding the burn out phenomenon between the thin film resistor structure above the supporting structure and the conductive layer in the interconnection layer.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1H are cross-sectional schematic views of a method for forming a semiconductor device according to an embodiment of the present invention.

FIG. 2A to FIG. 2C are cross-sectional schematic views of steps for forming a recess in an isolation structure according to an embodiment of the present invention.

### DESCRIPTION OF THE EMBODIMENTS

The disclosure will be described more fully with reference to the drawings of the embodiments. However, the disclosure may also be embodied in various forms and should not be limited to the embodiments described herein. Thicknesses of layers and region in the drawings are exaggerated for clarity. The same or similar reference numerals indicate the same or similar elements, which will not be repeated one by one in the following paragraphs.

It will be understood that when an element is referred to as being “on” or “connected to” another element, the element may be directly on the other element or connected to the other element, or there may be an intervening element. When an element is referred to as being “directly on” or “directly connected to” another element, there is no intervening element. As used herein, “connection” may refer to physical and/or electrical connection, and “electrical connection” or “coupling” may be that there is another element between two elements.

“About”, “approximately”, or “substantially” used herein includes the mentioned value and the average value within an acceptable deviation range from the specific value that persons with ordinary skill in the art can determine, taking into account the measurement in discussion and the specific amount of error (that is, limitations of a measurement system) associated with the measurement. For example, “about” may mean within one or more standard deviations or within ±30%, ±20%, ±10%, or ±5% of the stated value. Furthermore, an acceptable deviation range or standard deviation may be selected for “about”, “approximately”, or “substantially” used herein according to optical properties, etching properties, or other properties, and one standard deviation does not need to be applied to all properties.

Terminology used herein is used only to describe illustrative embodiments and does not limit the disclosure. In such cases, the singular form includes the plural form unless the context dictates otherwise.

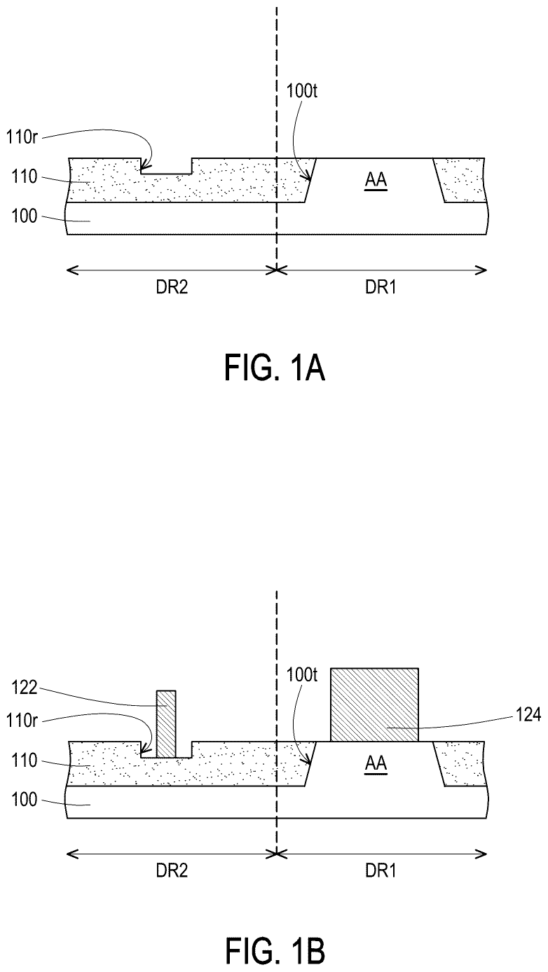

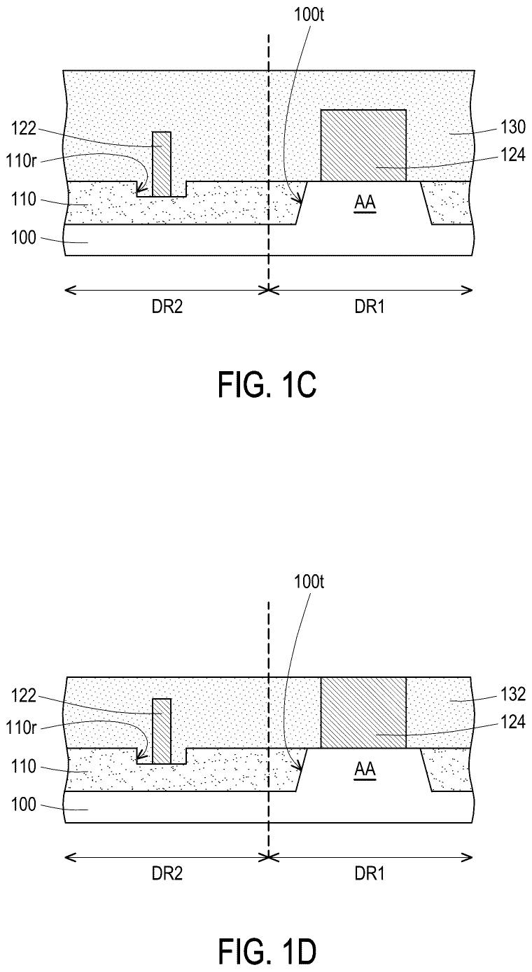

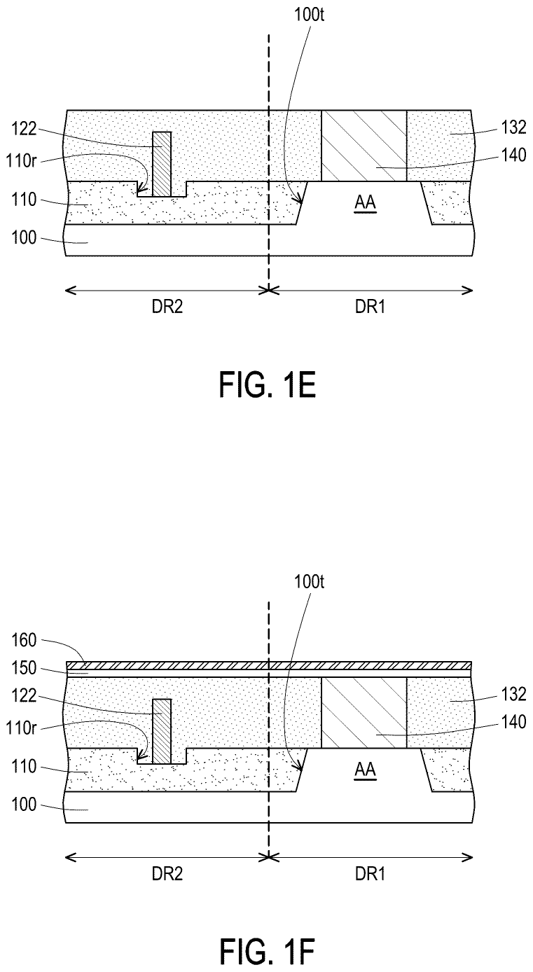

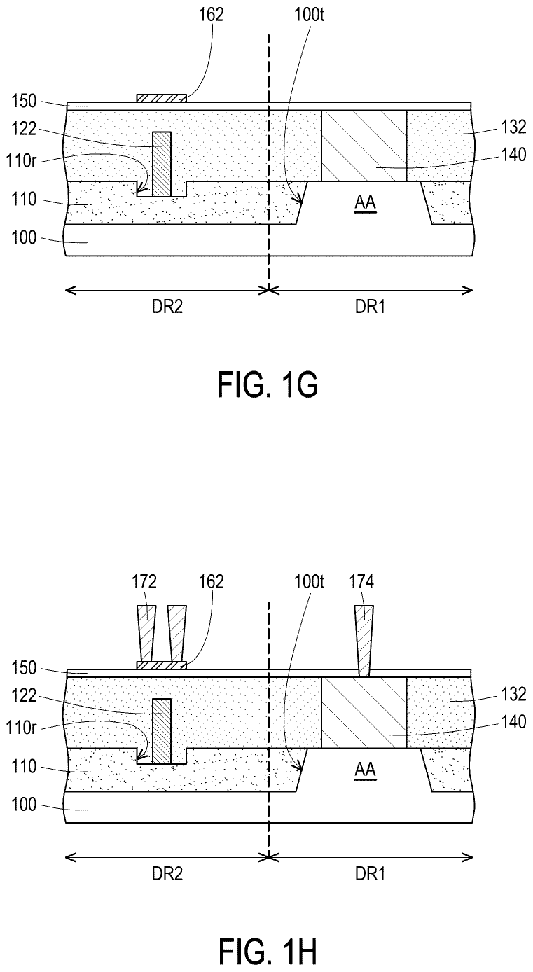

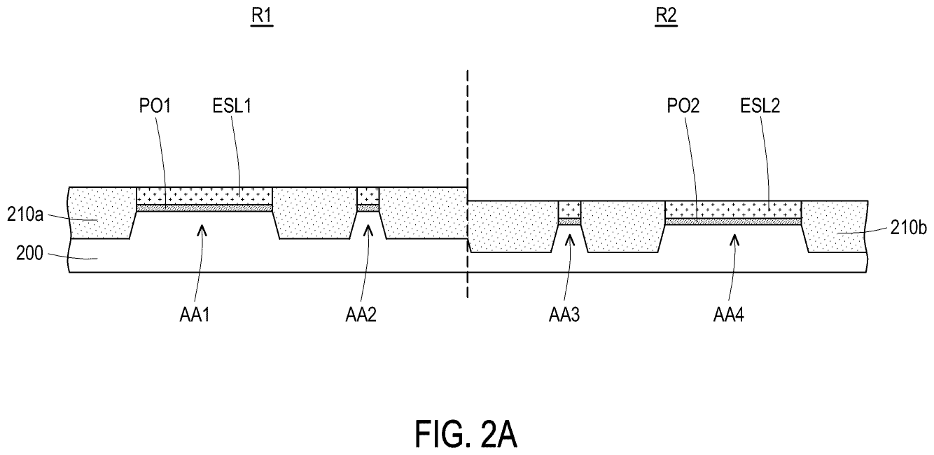

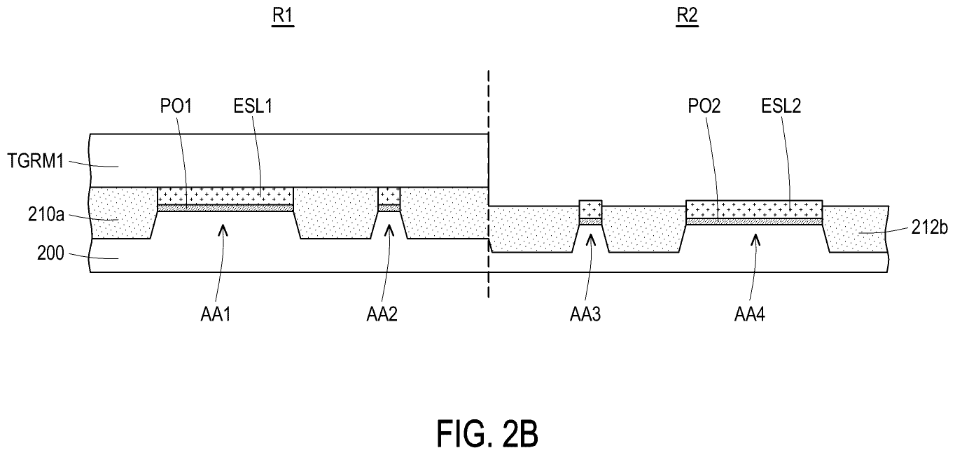

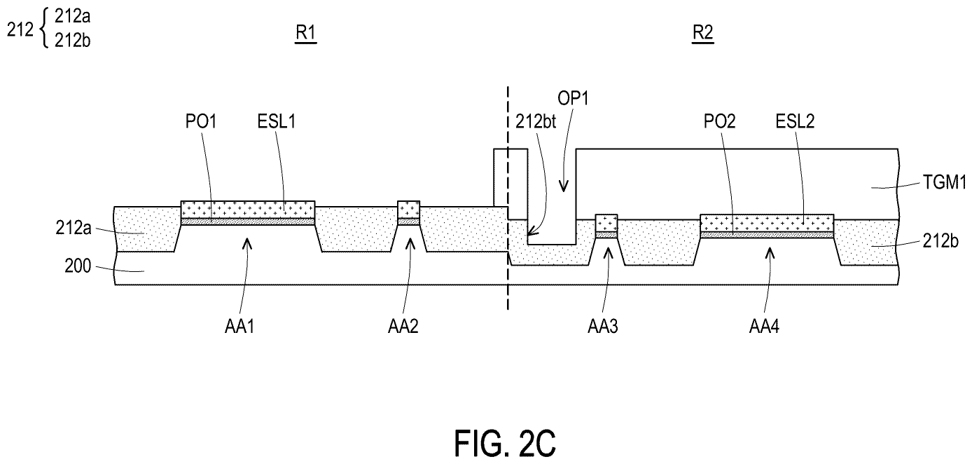

FIG. 1A to FIG. 1H are cross-sectional schematic views of a method for forming a semiconductor device according to an embodiment of the present invention. FIG. 2A to FIG. 2C are cross-sectional schematic views of steps for forming a recess in an isolation structure according to an embodiment of the present invention.

First, referring to FIG. 1A, a substrate 100 is provided. The substrate 100 includes an active region AA defined by an isolation trench 100t. In some embodiments, the substrate 100 may include a first device region DR1 where the active region AA is disposed, and a second device region DR2 adjacent to the first device region DR1. In some embodiments, the first device region DR1 may be a region where active elements (e.g., transistors) are disposed. In some embodiments, the second device region DR2 may be a region where passive elements (e.g., resistors) are disposed.

The substrate 100 may include a semiconductor substrate or a semiconductor on insulator (SOI) substrate. The semiconductor material in the semiconductor substrate or the SOI substrate may include an element semiconductor, an alloy semiconductor, or a compound semiconductor. For example, the elemental semiconductor may include Si or Ge. The alloy semiconductor may include SiGe, SiGeC, etc. The compound semiconductor may include SiC, an III-V semiconductor material, or an II-VI semiconductor material. The III-V semiconductor material may include GaN, GaP, GaAs, AIN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs. The II-VI semiconductor material may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type that is complementary to the first conductivity type. For example, the first conductivity type may be N type, and the second conductivity type may be P type.

Then, an isolation structure 110 is formed in the isolation trench 100t. In some embodiments, the isolation structure 110 may include one or more dielectric materials. The dielectric materials may include oxides (e.g., silicon oxide), tetraethyl orthosilicate (TEOS), nitrides (e.g., silicon nitride, silicon oxynitride etc.), carbides (e.g., silicon carbide, silicon oxycarbide, etc.), or the like. In some embodiments, the isolation structure 110 may be, for example, a shallow trench isolation (STI) structure, but is not limited thereto.

Then, a recess 110r is formed in the isolation structure 110. In some embodiments, the recess 110r may be located in the second device region DR2. In some embodiments, the recess 110r may be formed through the following steps. First, a mask pattern (which may be corresponded to the mask pattern TGM1 shown in FIG. 2C) is formed on the substrate 100, wherein the mask pattern has an opening (which may be corresponded to the opening OP1 shown in FIG. 2C) exposing the isolation structure 110. Then, a portion of the isolation structure 110 is removed through the opening to form the recess 110r. In some embodiments, the top surface of the substrate 100 in the active region AA may be formed to be higher than the bottom surface of the recess 110r in the isolation structure 110.

In some embodiments, the mask pattern used to form the recess 110r may be integrated with the mask pattern used to control the step height of other regions of the substrate 100. For example, as shown in FIG. 2C, the mask pattern TGM1 may be a mask pattern used to control the step height of the first region R1 (e.g., a region where low-voltage semiconductor elements are disposed). When a portion of the first portion 210a of the isolation structure 210 located in the first region R1 is removed to control the step height, a portion of the second portion 212b of the isolation structure 212 located in the second region R2 (e.g., a region where medium-voltage or high-voltage semiconductor elements are disposed) that is exposed by the opening OP1 is also removed simultaneously through the opening OP1 formed in the mask pattern TGM1, so as to form a recess 212bt.

In this embodiment, the recess 212bt may be formed through the following steps. First, referring to FIG. 2A, a substrate 200 is provided. The substrate 200 may include a first region R1 and a second region R2. The first region R1 may be a region where the low-voltage semiconductor elements are disposed. The second region R2 may be a region where the medium-voltage or high-voltage semiconductor elements are disposed. In some embodiments, the operating voltage (e.g., may be but not limited to 8V) of the medium-voltage semiconductor elements may be greater than the operating voltage (e.g., may be but not limited to 0.9V) of the low-voltage semiconductor elements. In some embodiments, the operating voltage (e.g., may be but not limited to 20V or 32V) of the high-voltage semiconductor elements may be higher than the operating voltage (e.g., may be but not limited to 8V) of the medium-voltage semiconductor elements.

The substrate 200 may include active regions AA1, AA2, AA3, AA4 defined by the isolation structure 210, wherein the first portion 210a of the isolation structure 210 in the first region R1 defines the active regions AA1 and AA2, while the second portion 210b of the isolation structure 210 in the second region R2 defines the active regions AA3 and AA4. In some embodiments, the isolation structure 210 may be formed through the following steps. First, a pad oxide material layer (not shown), an etching stop material layer (not shown), and a patterned mask layer (not shown) are sequentially formed on the substrate 200. Then, portions of the etching stop material layer exposed by the patterned mask layer and the pad oxide material layer and a portion of the substrate 200 under the portions of the etching stop material layer are removed to form pad oxide layers PO1 and PO2, etching stop layers ESL1 and ESL2, and an isolation trench. Afterwards, a dielectric material layer is formed on the substrate 200, covering the pad oxide layers PO1 and PO2 and the etching stop layers ESL1 and ESL2, and filling the isolation trench. Subsequently, a planarization process such as a chemical mechanical polishing (CMP) process is performed on the dielectric material layer to form the isolation structure 210 that exposes the etching stop layers ESL1 and ESL2.

Then, referring to FIG. 2B, a mask pattern TGRM1, covering the first region R1 of the substrate 200 and exposing the second region R2 of the substrate 200, is formed. Subsequently, a portion of the second portion 210b of the isolation structure 210 exposed by the mask pattern TGRM1 is removed to form the second portion 212b of the isolation structure 212. In other words, the mask pattern TGRM1 may be used to control the step height of the isolation structure 210 in the second region R2.

Then, referring to FIG. 2B and FIG. 2C, after forming the second portion 212b of the isolation structure 212, the mask pattern TGRM1 is removed. Subsequently, a mask pattern TGM1, covering the second region R2 of the substrate 200 and exposing the first region R1 of the substrate 200, is formed, wherein the mask pattern TGM1 has an opening OP1 exposing the second portion 212b of the isolation structure 212. Next, a portion of the first portion 210a of the isolation structure 210 exposed by the mask pattern TGM1 is removed to form the first portion 212a of the isolation structure 212. In other words, the mask pattern TGM1 may be used to control the step height of the isolation structure 210 in the first region R1. In this embodiment, based on the mask pattern TGM1 is formed to have the opening OP1 exposing the second portion 212b of the isolation structure 212, a portion of the second portion 212b of the isolation structure 212 exposed by the opening OP1 is also removed while the portion of the first portion 210a of the isolation structure 210 located in the first region R1 is removed, so as to form a recess 212bt.

Then, returning to FIG. 1A and referring to FIG. 1B simultaneously, a supporting structure 122 and a sacrificial gate structure 124 are formed on the recess 110r of the isolation structure 110 and on the active region AA of the substrate 100, respectively. The supporting structure 122 and the sacrificial gate structure 124 may be made of the same material. For example, the supporting structure 122 and the sacrificial gate structure 124 may be made of polysilicon. In some embodiments, the supporting structure 122 and the sacrificial gate structure 124 may have the same thickness, but since the bottom surface of the recess 110r of the isolation structure 110 is lower than the top surface of the active region AA of the substrate 100, the top surface of the supporting structure 122 may be at a horizontal height lower than the top surface of the sacrificial gate structure 124.

Then, referring to FIG. 1B and FIG. 1C, a first dielectric material layer 130, covering the sacrificial gate structure 124 and the supporting structure 122, is formed on the substrate 100. In some embodiments, the first dielectric material layer 130 may include dielectric materials such as nitrides (e.g., silicon nitride). In some embodiments, the top surface of the sacrificial gate structure 124 is at a first distance from the top surface of the first dielectric material layer 130, and the top surface of the supporting structure 122 is at a second distance from the top surface of the first dielectric material layer 130, wherein the second distance is greater than the first distance.

Subsequently, referring to FIG. 1C and FIG. 1D, a portion of the first dielectric material layer 130 is removed to form a first dielectric layer 132 that exposes the top surface of the sacrificial gate structure 124. In this embodiment, the sacrificial gate structure 124 may serve as an etching stop layer for removing the first dielectric material layer 130. Based on the top surface of the sacrificial gate structure 124 is higher than the top surface of the supporting structure 122, the first dielectric layer 132 that exposes the top surface of the sacrificial gate structure 124 still covers the top surface of the supporting structure 122.

Then, referring to FIG. 1D and FIG. 1E, the sacrificial gate structure 124 is removed to define a space in the first dielectric layer 132 for forming a gate structure 140. Subsequently, the gate structure 140 is formed in the space. The above steps are included in the process of replacing the polysilicon gate with the metal gate. Since the top surface of the supporting structure 122 is not exposed and is covered by the first dielectric layer 132, only the sacrificial gate structure 124 is replaced by the gate structure 140. In other words, the gate structure 140 may include a metal material different from the material of the supporting structure 122.

In some embodiments, the gate structure 140 may include a gate dielectric layer, a high dielectric constant (high-k) layer, a capping layer, a metal layer (also known as a work-function metal layer), and a conductive layer (also known as a metal gate electrode) sequentially disposed on the active region AA of the substrate 100. The gate dielectric layer may include any material suitable for the gate dielectric layer, such as oxides (e.g., silicon oxide). The high-k layer may include dielectric materials with high dielectric constants. For example, the dielectric materials with the high dielectric constants may be materials with the dielectric constants greater than that of silicon oxide (about 3.9). In some embodiments, the high-k layer may include HfSiO, HfSiON, HfO, LaO, LaAlO, ZrO, ZrSiO, HfZrO, or a combination thereof. The capping layer may include LaO, Dy₂O₃, or a combination thereof. The metal layer may include N-type work-function metal and/or P-type work-function metal. For example, N-type work-function metal may be TiN, TaC, Ta, TaSiN, Al, TiAlN, Ta, Ti, Hf, or a combination thereof. P-type work-function metal may be TiN, W, WN, Pt, Ni, Ru, TaCN, or TaCNO. The conductive layer may include low-resistance metal materials such as Al, W, or TiAl.

Then, referring to FIG. 1E and FIG. 1F, a second dielectric layer 150 is formed on the first dielectric layer 132. In some embodiments, the second dielectric layer 150 may include any suitable dielectric material, such as oxides (e.g., tetraethyl orthosilicate (TEOS)). Subsequently, a thin film resistor layer 160 is formed on the second dielectric layer 150. In some embodiments, the thin film resistor layer 160 may include a material with higher resistance than the metal material of the gate structure 140. For example, the thin film resistor layer 160 may include a material with higher resistance than the metal material of the metal gate electrode of the gate structure 140. For example, the thin film resistor layer 160 may include TiN with higher resistance than Al, but is not limited thereto.

After that, referring to FIG. 1F and FIG. 1G, a patterning process is performed on the thin film resistor layer 160 to form a thin film resistor structure 162 over the recess 110r of the isolation structure 110. As a result, since the supporting structure 122 under the thin film resistor structure 162 is not affected by the process of replacing the polysilicon gate with the metal gate, for example, the material of the supporting structure is not replaced by the metal material during the process of replacing the polysilicon gate with the metal gate. As such, the supporting structure does not have extrusion phenomenon after undergoing the thermal cycling processes during the FEOL process and/or the BEOL process, and thereby avoiding the burn out phenomenon between the thin film resistor structure 162 and the conductive layer in the interconnection layer subsequently formed on the thin film resistor structure 162.

In some embodiments, the first dielectric layer 132 may be formed to surround the gate structure 140 and the supporting structure 122, and the first dielectric layer 132 may expose the top surface of the gate structure 140 and may include a portion interposed between the thin film resistor structure 162 and the supporting structure 122 and covering the top surface of the supporting structure 122. In some embodiments, the second dielectric layer 150 may be formed to include a portion in contact with the top surface of the gate structure 140 and a portion interposed between the thin film resistor structure 162 and the supporting structure 122. In some embodiments, the bottom surface of the thin film resistor structure 162 in contact with the second dielectric layer 150 may be higher than the top surface of the gate structure 140 in contact with the second dielectric layer 150.

Then, referring to FIG. 1G and FIG. 1H, conductive vias 172 electrically connected to the thin film resistor structure 162 and conductive vias 174 electrically connected to the gate structure 140 are formed. The thin film resistor structure 162 may be electrically connected to the subsequently formed interconnect layer above it through the conductive vias 172. The gate structure 140 may be electrically connected to the interconnection layer subsequently formed on the gate structure 140 through the conductive vias 174. In some embodiments, the gate structure 140 may be electrically connected to the thin film resistor structure 162 through the conductive vias 174, the interconnection layer, and the conductive vias 172, but is not limited thereto. In other embodiments, the gate structure 140 may not be electrically connected to the thin film resistor structure 162. In some embodiments, the supporting structure 122 may be electrically floating, for example, the supporting structure 122 may be electrically isolated from the thin film resistor structure 162, the gate structure 140, and/or the interconnection layer.

Hereinafter, a semiconductor device according to an embodiment of the disclosure will be illustrated with reference to FIG. 1H. The semiconductor device of the embodiment may be formed by the method described above, but not limited thereto.

Referring to FIG. 1H, the semiconductor device includes a substrate 100, an isolation structure 110, and a thin film resistor structure 162. The substrate 100 includes an active region AA defined by an isolation trench 100t. The isolation structure 110 is disposed in the isolation trench 100t and includes a recess 110 r. The thin film resistor structure 162 is disposed over the recess 110r. In some embodiments, the top surface of the active region AA of the substrate 100 may be higher than the bottom surface of the recess 110r of the isolation structure 110.

In some embodiments, the semiconductor device may further include a supporting structure 122 disposed on the recess 110r and under the thin film resistor structure 162. In some embodiments, the semiconductor device may further include a gate structure 140 disposed on the active region AA, wherein the gate structure 140 may include a metal material different from a material of the supporting structure 122. In some embodiments, the supporting structure 122 may include polysilicon and may be electrically floating. In some embodiments, the top surface of the gate structure 140 may be higher than the top surface of the supporting structure 122. In some embodiments, the thin film resistor structure 162 may include a material having a higher resistance than the metal material of the gate structure 140.

In some embodiments, the semiconductor device may further include a first dielectric layer 132 disposed on the substrate 100 and surrounding the gate structure 140 and the supporting structure 122. The first dielectric layer 132 may expose the top surface of the gate structure 140 and may include a portion interposed between the thin film resistor structure 162 and the supporting structure 122 and covering the top surface of the supporting structure 122.

In some embodiments, the semiconductor device may further include a second dielectric layer 150 disposed on the first dielectric layer 132. The second dielectric layer 150 may include a portion in contact with the top surface of the gate structure 140 and a portion interposed between the thin film resistor structure 162 and the supporting structure 122. In some embodiments, the bottom surface of the thin film resistor structure 162 in contact with the second dielectric layer 150 may be higher than the top surface of the gate structure 140 in contact with the second dielectric layer 150.

In summary, in the semiconductor device and the method for forming the same, the isolation structure is designed to include the recess, so that the thin film resistor structure disposed over the recess is not affected by the supporting structure under the thin film resistor structure during the process of replacing the polysilicon gates with the metal gates, for example, the material of the supporting structure is not replaced by the metal material during the process of replacing the polysilicon gate with the metal gate. As such, the supporting structure does not have extrusion phenomenon after undergoing the thermal cycling processes during the FEOL process and/or the BEOL process, and thereby avoiding the burn out phenomenon between the thin film resistor structure and the conductive layer in the interconnection layer.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a substrate comprising an active region defined by an isolation trench;
an isolation structure disposed in the isolation trench and comprising a recess; and
a thin film resistor structure disposed over the recess.

2. The semiconductor device according to claim 1, wherein a top surface of the active region is higher than a bottom surface of the recess.

3. The semiconductor device according to claim 1, further comprising:
a supporting structure disposed on the recess and located under the thin film resistor structure.

4. The semiconductor device according to claim 3, further comprising:
a gate structure disposed on the active region and comprising a metal material different from a material of the supporting structure.

5. The semiconductor device according to claim 4, wherein the supporting structure comprises polysilicon and is electrically floating.

6. The semiconductor device according to claim 4, wherein a top surface of the gate structure is higher than a top surface of the supporting structure.

7. The semiconductor device according to claim 4, wherein the thin film resistor structure comprises a material having a resistance higher than the metal material of the gate structure.

8. The semiconductor device according to claim 4, further comprising:
a first dielectric layer disposed on the substrate and surrounding the gate structure and the supporting structure,
wherein the first dielectric layer exposes a top surface of the gate structure and comprises a portion interposed between the thin film resistor structure and the supporting structure and covering a top surface of the supporting structure.

9. The semiconductor device according to claim 8, further comprising:
a second dielectric layer disposed on the first dielectric layer and comprising a portion in contact with the top surface of the gate structure and a portion interposed between the thin film resistor structure and the supporting structure.

10. The semiconductor device according to claim 9, wherein a bottom surface of the thin film resistor structure in contact with the second dielectric layer is higher than the top surface of the gate structure in contact with the second dielectric layer.

11. A method of forming a semiconductor device, comprising:
providing a substrate comprising an active region defined by an isolation trench;
forming an isolation structure in the isolation trench;
forming a recess in the isolation structure; and
forming a thin film resistor structure over the recess.

12. The method according to claim 11, wherein a top surface of the active region is formed to be higher than a bottom surface of the recess.

13. The method according to claim 11, further comprising:
forming a supporting structure on the recess, wherein the supporting structure is formed under the thin film resistor structure.

14. The method according to claim 13, further comprising:
forming a gate structure on the active region, the gate structure comprising a metal material different from a material of the supporting structure.

15. The method according to claim 14, wherein the supporting structure comprises polysilicon and is electrically floating.

16. The method according to claim 14, wherein the thin film resistor structure comprises a material having a resistance higher than the metal material of the gate structure.

17. The method according to claim 14, further comprising:
forming a first dielectric layer surrounding the gate structure and the supporting structure on the substrate,
wherein the first dielectric layer exposes a top surface of the gate structure and comprises a portion interposed between the thin film resistor structure and the supporting structure and covering a top surface of the supporting structure.

18. The method according to claim 17, wherein a step of forming the supporting structure and the gate structure comprises:
forming the supporting structure and a sacrificial gate structure on the recess and the active region, respectively, wherein the supporting structure and the sacrificial gate structure are made of the same material;
forming a first dielectric material layer covering the sacrificial gate structure and the supporting structure on the substrate;
removing a portion of the first dielectric material layer to form the first dielectric layer exposing a top surface of the sacrificial gate structure;
removing the sacrificial gate structure to define a space in the first dielectric layer for forming the gate structure; and
forming the gate structure in the space.

19. The method according to claim 17, further comprising:
forming a second dielectric layer on the first dielectric layer, wherein the second dielectric layer comprises a portion in contact with the top surface of the gate structure and a portion interposed between the thin film resistor structure and the supporting structure.

20. The method according to claim 19, wherein a bottom surface of the thin film resistor structure in contact with the second dielectric layer is higher than the top surface of the gate structure in contact with the second dielectric layer.
